(19) United States
(12) Patent Application Publication
(10) Pub. No.: US 2010/0193920 A1
(43) Pub. Date: Aug. 5, 2010

(54) SEMICONDUCTOR DEVICE, LEADFRAME AND METHOD OF ENCAPSULATING

(75) Inventors: Yong Chern Poh, Melaka (MY); Yang Hong Heng, Melaka (MY); Pey Eik Foo, Melaka (MY)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/363,120

(22) Filed: Jan. 30, 2009

(51) Int. Cl. H01L 21/56; H01L 23/495

(52) U.S. Cl. 257/676; 438/123; 257/E23.031; 257/E21.502

(57) ABSTRACT

A semiconductor device is disclosed having a leadframe comprising a first chip island and a second chip island. Each chip island of the leadframe has a first face and a second face. A first chip is attached to the first face of the first chip island and a second chip attached to the first face of the second chip island. A layer of encapsulation material forming an encapsulation material layer covers the second faces of the first and second chip islands where the thickness of the encapsulation material layer along the second face of the first chip island is different from the thickness of the encapsulation material layer along the second face of the second chip island.

### FIELD OF THE INVENTION

This invention relates generally to semiconductor devices and packaging of semiconductor devices. More particularly this invention relates to a semiconductor device, leadframe and method of encapsulating a semiconductor device for reducing and minimizing void formations in the encapsulation material encapsulating the semiconductor chips and components of the semiconductor device while optimizing heat dissipation of the semiconductor chips.

### BACKGROUND

In end of line processes of packaging semiconductor devices, semiconductor chips together with other components of the semiconductor device, such as bonding wires and the chip carrier or leadframe that support the chips, are encapsulated with an encapsulation or mold material. A mold is arranged relative to the components to form a mold cavity for the encapsulation material to flow through for forming the fully encapsulated package of the semiconductor device.

The encapsulation material protects the chip and other components of the semiconductor device from mechanical and environmental stresses and also provides a thermal path for the heat that is dissipated from the chip. However, voids formed in the encapsulation material during the manufacturing process may cause strain in the voids from temperature cycles, humidity fluctuations, and the like, during the operation of the semiconductor device which may lead to device failure.

A method of encapsulating a semiconductor device is needed to alleviate the above problems for reducing and minimizing void formations in the isolation layer of encapsulation material encapsulating the semiconductor chips and semiconductor device components while optimizing heat dissipation of the semiconductor chips.

### SUMMARY

An aspect of the invention is a semiconductor device, comprising a leadframe comprising a first chip island and a second chip island, each chip island having a first face and a second face; a first chip attached to the first face of the first chip island; a second chip attached to the first face of the second chip island; and a layer of encapsulation material forming an encapsulation material layer covering the second faces of the first and second chip islands, the thickness of the encapsulation material layer along the second face of the first chip island being different from the thickness of the encapsulation material layer along the second face of the second chip island.

An aspect of the invention is a method of encapsulating a semiconductor device that comprises providing a leadframe having a first chip island and a second chip island, each chip island having a first face and a second face, the first chip island offset relative to the second chip island, the first chip island and the second chip island for receiving semiconductor chips; fixing a first chip to the first surface of the leadframe at the first chip island; fixing a second chip to the first surface of the leadframe at the second chip island, wire bonding wires to the first and second chips; arranging a mold frame with respect to the second surface of the leadframe to form a gap between the second surface of the first chip island and the second chip island and a surface of the mold frame; and encapsulating with an encapsulation material flowing into the gap to form an encapsulation material layer covering the second face of first chip island and the second face of the second chip island, the thickness of the encapsulation material layer along the second face of the first chip island being different from the thickness of the encapsulation material layer along the second face of the second chip island.

An aspect of the invention is a leadframe comprising a first chip island and a second chip island, each chip island having a first face and a second face; the first face of the first chip island for receiving a first chip, the first face of the second chip island for receiving a second chip, the first chip island offset relative from the second chip island.

An aspect of the invention is a method of making a multi-downset leadframe comprising providing a leadframe having a first surface and a second surface; stamping a first chip island for receiving a first semiconductor chip; and stamping a second chip island offset relative to the first chip island for receiving a second semiconductor chip.

### BRIEF DESCRIPTION OF THE DRAWINGS

In order that embodiments of the invention may be fully and more clearly understood by way of non-limitative examples, the following description is taken in conjunction with the accompanying drawings in which like reference numerals designate similar or corresponding elements, regions and portions, and in which:

FIG. 1 shows cross-sectional front view of a semiconductor device having a multi-chip island leadframe configuration in accordance with an embodiment of the invention;

FIG. 2A-D show an enlarged cross-sectional front view of a multi-chip island leadframe for a chip set configuration (FIG. 2A), array configurations (FIG. 2B-2C), and slit die pad configuration (FIG. 2D) in accordance with embodiments of the invention;

FIG. 3 shows an enlarged cross-sectional side view of a semiconductor device for a chip set configuration showing encapsulation material isolation thickness for the driver and power chip of the chip set in accordance with an embodiment of the invention;

FIG. 4 shows an enlarged cross-sectional top view of a semiconductor device for a chip set configuration showing the die pad areas of the driver chip and the power chip of the chip set and wire bonding for the driver and power chip in the chip set in accordance with an embodiment of the invention;

FIG. 5A-C show an enlarged cross-sectional side view of a molding system with mold form positioned (FIG. 5A) for encapsulating (FIG. 5B) the semiconductor components with molding material, and the compound meeting point of molding material (FIG. 5C); and

FIG. 6 shows a flow chart of a method in accordance with an embodiment of the invention.

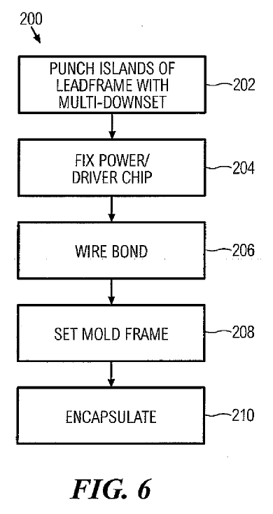

### DETAILED DESCRIPTION

A semiconductor device, leadframe and method of encapsulating at least a pair or set of chips within a semiconductor device are disclosed. More specifically, the leadframe and the method of encapsulating disclosed reduce and minimize the formation of voids and/or air traps in the encapsulating material of the semiconductor device. The leadframe is arranged with multi-chip islands or downsets to position chips attached thereto having different thicknesses of isolation layer of encapsulating material commensurate with the power consumption for each respective chip to minimize void formations in the encapsulation material and optimize heat dissipation of the chip. The design of the leadframe in accordance with an embodiment of the invention achieves improved mold flow behavior to minimize formation of voids in the encapsulation layer. The effects of wire sweep during the encapsulation process is also limited due to the reduced length of wires required for wire bonding to the chips positioned on the chip islands or downsets that are offset higher or nearer the top surface of the semiconductor device relative to the other chips on the lower chip islands or downsets.

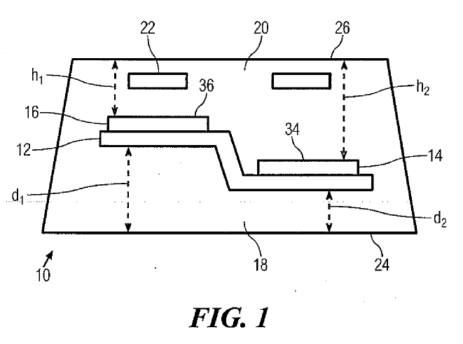

Referring to FIG. 1, a two dimensional cross-sectional view of a semiconductor device 10 having a multi-chip island leadframe 12 configuration is shown in accordance with an embodiment of the invention. The leadframe 12 is arranged with multi-chip islands or downsets to position chips 14,16 attached thereto such that different thicknesses of isolation layer d₁,d₂ of encapsulating material is provided commensurate with the power consumption for each respective chip. This arrangement minimizes void formations in the encapsulation material and optimizes heat dissipation of the chip. Advantageously, as a result of having a multi-chip island or multi-downset configuration, the length of the bonding wires 110,112 are also minimized which aids in minimizing the occurrence of wire sweep 114.

In order to optimize the heat dissipation of chips, the thickness of the isolation layer of encapsulation material is minimized. As discussed above, in a conventional semiconductor device, the layer thickness of the encapsulation material is minimized in the region below the surface of the leadframe opposite the side of the leadframe where the chips, such as power chip and driver chip are fixed. The thickness of the isolation layer is typically a minimum, for example 0.35 mm, and is constant along the bottom surface of the leadframe. The measured distance is measured from the bottom surface of the leadframe to the bottom surface of the semiconductor device, i.e. the surface of the bottom layer of encapsulation material.

While this minimum thickness of the isolation layer is advantageous in terms of heat dissipation, such a thin thickness is prone to formation of voids or air traps in the encapsulation material due to high mold flow resistance causing imbalance mold flow during encapsulation. There are a number of reasons voids form in the encapsulation material, for example the flow of molding material is inhibited by the increased resistance of the mold flow due to the smaller gap and the viscous nature of the molding material and flow phenomena exhibited in the molding material through such thin gaps. Producing such a thin layer of isolation material is difficult to form between the surface of the leadframe and the wall of the mold form through which the encapsulation material flows during the molding process. The liquid encapsulation material often fails to flow continuously to form a homogenous isolation layer in the thin gap defined between the leadframe and the mold form. As a consequence, voids are formed in the isolation layer which may lead to device failure due to strain in the voids stemming from a number of sources such as temperature cycles, humidity fluctuations, and the like, which are generated during manufacturing and operation of the semiconductor device. The formation of voids is compounded when larger areas of thin isolation layer are attempted.

Another issue of concern with the formation of the encapsulation material is wire sweep which occurs on bonding wires in conventional semiconductor devices during the molding processes. As more wires are packaged in smaller wire gaps, increasing wire density is increasing the significant impact wire sweep has on semiconductor device fabrication and performance. The bonding wires are bonded to the die pads of the semiconductor chips and the connecting bars which are typically provided for connection of the semiconductor device to external devices. The bonding wires are typically in the top layer of encapsulation material of the conventional semiconductor device which typically has a distance that is measured from between the top of the semiconductor chips of the power die pad and the driver die pad to the top surface of the semiconductor device, i.e. the surface of the top layer of encapsulation material. The thickness of the isolation layer is typically constant along the top surface of the die pads of the semiconductor chips and the surface of the semiconductor device. The molding encapsulation material melt flow exerts a drag force on the bonding wires causing deformation of the bonding wires which may result in adjacent wires to touch with each other or wire breakage causing device failure.

An embodiment of the invention includes molded multi-chip semiconductor devices 10 that have at least two semiconductor chips 14,16. Each chip may have different power consumption rankings and different heat dissipation requirements. An embodiment realizes that not all of the chips in the multi-chip semiconductor require the optimum thin isolation bottom layer of encapsulation material 18, for example 0.35 mm, to maximize heat dissipation. Mold void problems are substantially avoided by limiting the areas of optimum thin isolation layers in the total area of chip areas. The leadframe 12 has a multi-downset configuration. The downset of the leadframe is the stepped first portion of the leadframe offset relative to a second stepped portion of the leadframe. The downset provides an offset for a mounting paddle, or other die mounting portion to the leadframe relative to the lead fingers of the lead frame. The chips are fixed to the leadframe in the downset that positions the chip so a thickness of isolation layer d₁,d₂ of encapsulating material commensurate with the power consumption for the respective chip. This configuration minimizes void formations or air traps in the encapsulation material and optimizes heat dissipation of the chip. The chips having relatively lower power consumption require little heat dissipation and are attached to a downset in the leadframe that provides a larger gap d₁ between the leadframe bottom surface and the mold form, for example greater than 0.35 mm, such as 0.60 mm. This is the distance from the bottom surface of the leadframe to the bottom surface 24 of the semiconductor device 10 once the mold form is removed after the encapsulation process. The larger gap may be for example more than about 0.35 mm or the like. The chips having relatively greater power consumption demanding greater heat dissipation are attached to a downset in the leadframe that provides a smaller gap d₂ between the leadframe bottom surface opposite the chip and the mold form. The thinner gap may be for example less than about 0.35 mm or the like. Different die pad heights can be achieved by different downset during leadframe stamping.

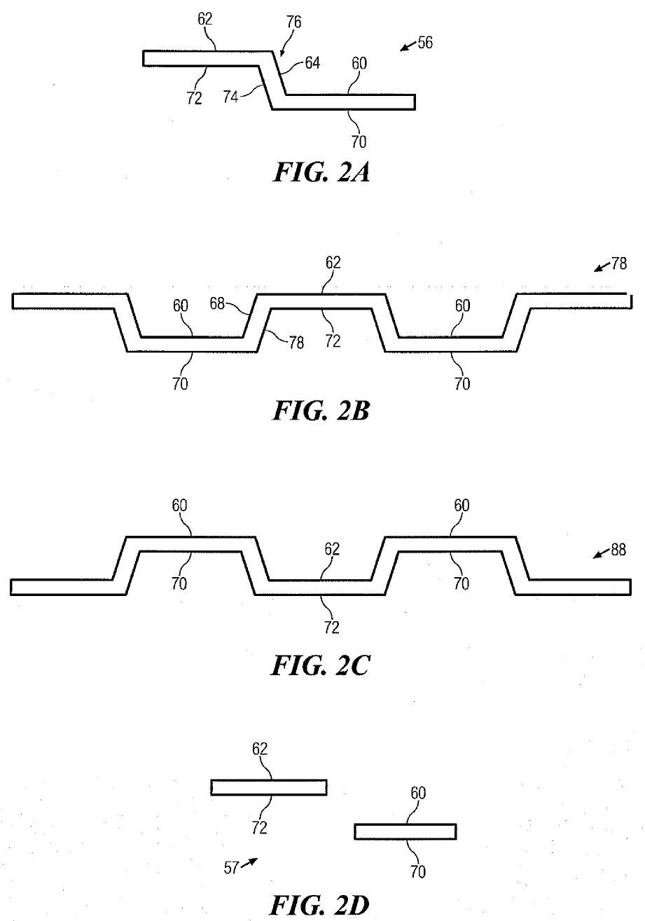

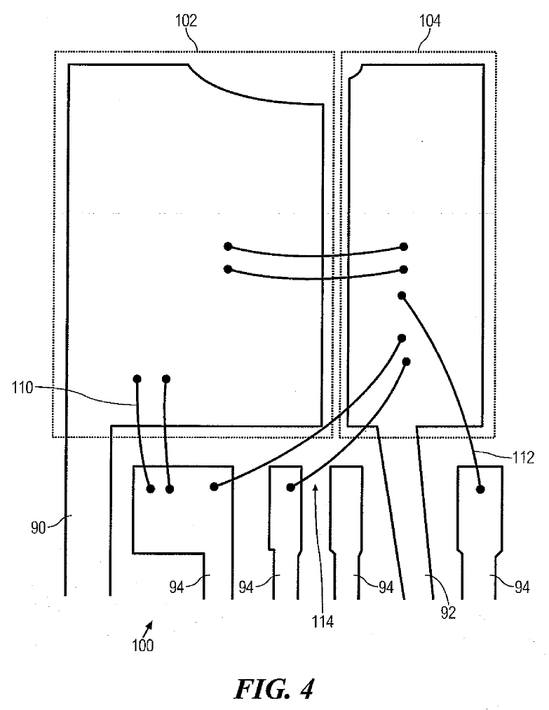

The bonding wires 110,112, shown in FIG. 4, are bonded to the die pads 36,34 of the semiconductor chips 14,16 and the connecting sections 22. In other embodiments the die pads are separate die pads arranged in a slit die pad multi-chip island configuration 57 as shown in FIG. 2D. The connection bars 22 are typically provided for connection of the semiconductor device to external devices (not shown). The bonding wires are in the top layer of encapsulation material 20 of the conventional semiconductor device 10 which has a distance h₁,h₂ measured from between the top of the semiconductor chips 14,16 of the power die pad 34 and the driver die pad 36 to the top surface 26 of the semiconductor device 10, i.e. the surface of the top layer of encapsulation material 20. In an embodiment, a first wire may be bonded from the first chip to a leadframe output and a second wire may be bonded from the second chip to a leadframe output, where the first wire may be shorter than the second wire to minimize wire sweep.

In an embodiment, the thickness or width between top surface 26 of the semiconductor device 10 and the bottom surface 24 of the semiconductor device may be constant, and the planes formed by the top and bottom surfaces may be parallel to each other. The lead frame may have a first downset offset relative to a second downset, and the first chip may be attached to the first face of the first downset and the second chip may be attached to the first face of the second downset. The thickness of the encapsulation material layer along the second face of the first chip island may be arranged to be larger than the thickness of the encapsulation material along the second face of the second chip island. The ratio of thickness of the encapsulation material layer along the second face of the first chip island to the thickness of the encapsulation material layer along the second face of the second chip island may be arranged to be larger than for example 2.0. In other embodiments, the ratio of thickness may be less than 2.0 or larger than 2.0, for example 10.0 or larger and the like. It will be appreciate that different thickness ratios may be arranged for each particular configuration, chip set, or plurality of chip sets. The thickness of the encapsulation material layer along the second face of the first chip island may be arranged to be smaller than for example 1000 micrometer. The thickness of the encapsulation material layer along the second face of the first chip island may be arranged to be smaller than for example 500 micrometers. The thickness of the encapsulation material layer along the second face of the first chip island may be arranged to be larger than for example 1000 micrometer.

In an embodiment the first chip island of the leadframe and the second chip island of the leadframe may be contiguous forming a combined chip island. Where the chip islands are contiguous, a step may be between the first chip island and the second chip island of the leadframe. The first chip island and the second chip island may be arranged having a slit formed between the first chip island and the second chip island. The leadframe may have a plurality of chip islands.

In an embodiment, the multi-chip module package of the semiconductor device comprises a chip-set having two chips. The multi-chip island or multi-downset leadframe 56 for this embodiment is shown in FIG. 2A, and the corresponding semiconductor device for this embodiment is shown in FIG. 1. In other embodiments the die pads are separate die pads arranged in a multi-chip island configuration 57 as shown in FIG. 2D.

An example of chips in the chip set may comprise a power transistor chip, for example IGBT for switching high currents, COOLMOS, and a driver integrated circuit (IC) chip for controlling the power transistor timing. Package power consumption rating may be for example 40-80 W with an estimate of >95% for power chip. The power transistor chip demands greater heat dissipation with a higher power consumption rating than the driver IC chip. The power transistor chip is positioned in the downset of the multi-downset leadframe that forms a smaller gap between the bottom surface of the leadframe and the mold form. The driver IC chip is fixed in the downset of the multi-downset leadframe that forms a larger gap between the bottom surface of the leadframe and the mold frame. In an embodiment, the first chip may be for example a power transistor, and the second chip may be for example a logic integrated circuit. For example, first chip may be a power transistor that may have a current larger or voltage larger than the second chip. For example the power transistor may have a current larger than 1 A and/or a voltage larger than 20V, for example IGBT, power MOSFET, power JFET, vertical transistor or the like. The second chip may be an integrated circuit that for example consumes a current of a lower current or voltage. For example, the integrated circuit on the second chip island may consume a current of at most 100 mA during operation. With this configuration, void formation is minimized while optimizing heat dissipation.

In an embodiment, the multi-chip module package of the semiconductor device comprises multi-chip module package having two or more chips. The multi-chip island or multi-downset leadframe for this embodiment forms an array of chip islands. Such an array of chip islands or leadframe strip is shown in FIGS. 2B and 2C. It will be appreciated that in embodiments may be configured 57 with the die pads that are separate and arranged in a multi-chip island configuration 57 in slit die pad sections without bend 76 as shown in FIG. 2D. The multi-chip island or multi-downset leadframe comprises a chip island or downset for each chip or multiple chips in the semiconductor device. In this embodiment, each chip island is shifted relative to the adjacent chip island, and each chip island is on a different plane than an adjacent chip island. Each chip is attached to a corresponding chip island or downset that is positioned to form an appropriate gap between the bottom surface of the leadframe and the mold frame. The multi-chip island or multi-downset leadframe 12 has a first downset chip die pad support 60, for example for a chip with relatively higher power consumption rankings demanding higher heat dissipation, and a second chip die pad support surface portion 62, for example for a chip with relatively lower power consumption rankings demanding lower heat dissipation. The chips are bonded to the surfaces of the leadframe 60,62. The bend 76 or portion of the leadframe between the downsets has topside surface 64 and underside surface 74. The support portions of the downset of the leadframe have underside surfaces 70,72. Multi-downset configurations 78,88 are shown in FIG. 2B-2C comprising a plurality of relatively lower downsets and relatively higher downsets. The bend or portion of the leadframe between the downsets has topside surface 64,68 and underside surface 74,78. It will be appreciated that although FIG. 2B-2C show a plurality of downsets of two different heights, each downset may be configured with a different downset relative to other downsets, and the resulting gap and isolation layer may differ for each downset. The bottom encapsulation layer 18 may have a different height or thickness between each under surface 70,72 of a chip island or downset and the bottom surface 24 of the semiconductor device 10.

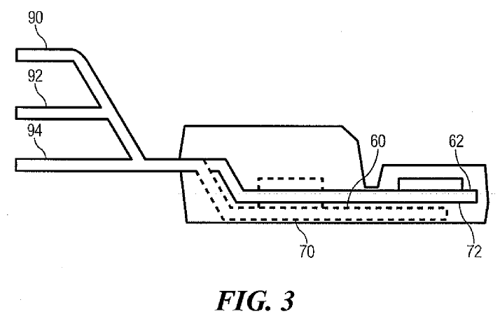

The specific gap formed or thickness of the bottom encapsulation layer 18 is commensurate with the particular power consumption and heat dissipation requirements specific to the chip. For example, for chips with relatively high power consumption, the gap formed between the bottom of the leadframe and the mold form is minimized such as about 0.35 mm to form an isolation layer of encapsulating material below the leadframe of the chip with high power consumption. Likewise, for chips with relatively low power consumption, the gap formed between the bottom of the leadframe and the mold form is larger such as about 0.6 mm to form an isolation layer of encapsulating material below the leadframe of the chip with lower power consumption. Referring to FIG. 3 shows a side cross-sectional side view of a chip set configuration and shows the difference in gaps formed. The leadframe outputs 90,92,94 of the leadframe and chips are shown.

FIG. 4 shows an enlarged cross-sectional top view 100 of a semiconductor device for a chip set configuration showing the die pad areas of the driver chip and the power chip of the chip set in accordance with an embodiment of the invention. The power consumption and corresponding heat dissipation requirement for the power chip is usually greater than the requirement of the driver chip, and accordingly in accordance with an embodiment of the invention, the gap and resulting isolation layer formed under the power chip is smaller than the gap and resulting isolation layer formed under the driver chip. The corresponding area of the two gaps and isolation layers corresponds with the area of the corresponding chip and downset of the multi-downset leadframe. The greater the area of the larger gap and corresponding resulting isolation layer formed increases the flow of the fluid encapsulation material during the packaging encapsulation process and results in minimizing the formation of voids in these areas, as well as the areas in the smaller gaps and resulting thinner isolation layers. In an embodiment the area of the power chip die pad area (B) 102 is greater than or equal to about ⅓ area of the total area of power chip die pad area (B) and the driver chip die pad area (A) 104 as shown in FIG. 4, Area B≧(Area A+Area B)⅓. The total area 100 of the combined die pad area of the chip island is shown. Bonding wires 110,112 to the respective chips and illustrates that wire sweep 114 is minimized. The length of the bonding wires to the chip on the higher downset relative to the other lower downset is shorter which minimizes the effects of wire sweep. As only a sub-sample of the chips require optimum heat dissipation, the other sample of chips are arranged on different downsets within the multi-downset leadframe to form the encapsulation layer with the greater thickness underneath the chips requiring the least optimum heat dissipation. This aids in minimizing void formation in the encapsulation layer.

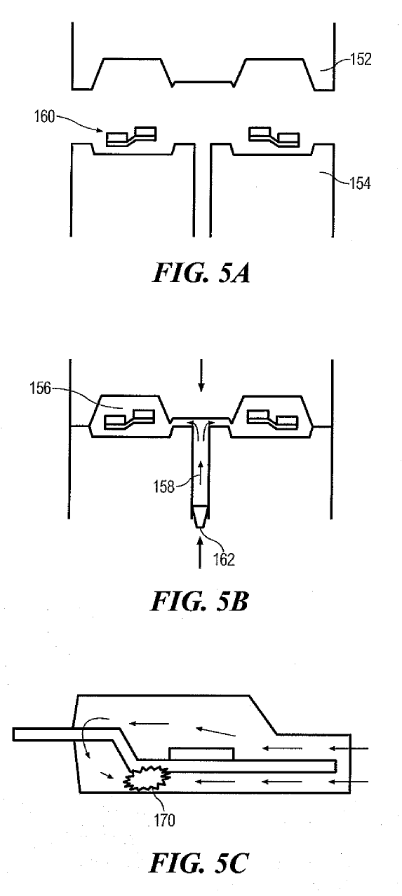

FIG. 5A-B show an enlarged cross-sectional side view of a molding system with mold form 150 positioned (FIG. 5A) for encapsulating (FIG. 5B) the semiconductor components 160 with molding compound or material 158. The molding encapsulation system comprises a top die 152 and a bottom die 154 that forms a mold cavity 156 for the mold compound 158 to flow during encapsulation to encapsulate the semiconductor device components 160 and form the semiconductor device 10 in accordance with an embodiment of the invention. The activation of a plunger 162 forces the encapsulation compound to flow into the mold cavity. With the configuration of the multi-chip island or multi-downset leadframe configuration, the mold compound flows faster in application at the top side of the die pad than the flow rate at the bottom side due to the larger mold flow front at the top thus lesser mold flow resistance. A compound flow meeting point 170 is shown in the bottom isolation layer as shown in FIG. 5C as mold compound flows from all areas and sides to aid in reducing void formation.

It will be understood that the principles of the embodiment discussed above with respect to the two chip or di-chip set may be applied to a plurality chip array embodiments, for example shown in FIGS. 2B and 2C. The principles of the multi-downset leadframe and the chip and corresponding gap and resulting isolation layer may be applied in a chip array module package having a plurality of chips. It will be appreciated that the chip islands may be arranged at different positions relative to other chip islands such that the thickness of the isolation layer along the second surface of the chip islands is different for each chip island.

FIG. 7 shows a flow chart of the method 200 of forming a semiconductor device in accordance with an embodiment of the invention. The first process step involves forming the multi-downset leadframe 202. The formation of the leadframe having multi-downsets forming chip islands comprises stamping or punching chip island or downset formations out of the leadframe. Different die pad heights can be achieved by different downset during leadframe stamping. In an embodiment, the power chip may have a thickness of for example 220 um, and the IC driver chip may have a thickness of for example 380 um. The material of the encapsulation material may be for example epoxy mold compound and the like. The material of the leadframe may be a Copper (Cu) alloy and the like. The wires for wire bonding may be for example Aluminum (Al)/Gold (Au)/Cu wires and the like, and the solder may be a tin (Sn) or lead (Pb) based solder or the like. The stamping tool design may be adjusted for stamping the multi-downset configuration of the leadframe for the desired application. In an embodiment a plurality of chip islands may be stamped. After the multi-downset leadframe is formed, the chips are fixed 204 in the downsets appropriate to the power rating of the respective chip.

The chips are wire bonded 206 with bonding wires. As the chips with lower power consumption ratings are arranged on the downsets forming larger isolation layers between the bottom surface of the leadframe and the bottom surface of the semiconductor device, the top of the die pad of the chip is at a higher or shifted level compared to the other chips that have greater power consumption ratings that are positioned on lower downsets relative to the higher downsets. A split die pad configuration may be provided without a connection bar between pads as shown in FIG. 2D. With this multi-downset configuration of the various embodiments, the bonding wires to the die chip pad to the chips on the higher downsets are shorter than the bonding wires to the die chip pad to the chips on the lower downsets. Wire bonding of chips in chip islands of different levels may be performed in the same manner in chips with level leadframe configurations. Such wire bonding techniques are conventional methods include wire bonding techniques such as with indexing using a heated block and a clamp, a carrier system with a pre-defined metal block, or the like. No additional steps are required for wire bonding of multi-downset configuration other than the leadframe transport to carrier prior to the wire bonding. The shorter wires results in reducing the occurrences of wire sweep since the wires are shorter to the chips in the higher downsets than the wires to the chips in the lower downsets due to the configuration of the multi-downset leadframe. The mold frame is arranged such that the resulting top and bottom surfaces of the semiconductor device are substantially parallel. Accordingly, the resulting gaps formed between the mold frame surfaces and the bottom surface of the leadframe varies according to the level of the downset of the leadframe. Similarly, the resulting gaps formed between the mold frame surfaces and the top surface of the chips die pads varies according to the level of the downset of the leadframe. The wire bonding of the chips attached to the multi-downset leadframe is accomplished with techniques known in the industry. For example, as shown in FIG. 4-5 due to the chips that are offset higher relative to the other lower offset chips the bonding wires are shorter to the higher offset chips than the other chips and the occurrence of wire sweep on these bonding wires is therefore reduced because the length of the wires is reduced.

The mold frame is arranged 208 relative to the multi-downset leadframe, bonding wires and chips to ensure gaps with the intended dimensions are formed between the second or bottom surface of the leadframe and the first surface of the mold form, and between the top of the chip die pads and the second surface of the mold form. The first and second surfaces of the mold form are substantially parallel. In this configuration, the thickness of the resulting encapsulation bottom layer varies along the second or bottom surface of the lead frame. Accordingly, the thickness of the encapsulation top layer also varies in a corresponding manner along the top surfaces of the die pads of the chips. The semiconductor device is encapsulated 210 with mold compound for a semiconductor device in accordance with an embodiment of the invention.

While embodiments of the invention have been described and illustrated, it will be understood by those skilled in the technology concerned that many variations or modifications in details of design or construction may be made without departing from the present invention.

What is claimed is:

1. A semiconductor device, comprising:
a leadframe comprising a first chip island and a second chip island, each chip island having a first face and a second face;
a first chip attached to the first face of the first chip island;
a second chip attached to the first face of the second chip island; and
a layer of encapsulation material forming an encapsulation material layer covering the second faces of the first and second chip islands, the thickness of the encapsulation material layer along the second face of the first chip island being different from the thickness of the encapsulation material layer along the second face of the second chip island.

2. The semiconductor device of claim 1 wherein the lead frame has a first downset offset relative to a second downset.

3. The semiconductor device of claim 2 wherein the first chip is attached to the first face of the first downset and the second chip is attached to the first face of the second downset.

4. The semiconductor device of claim 1 wherein the thickness of the encapsulation material layer along the second face of the first chip island is larger than the thickness of the encapsulation material along the second face of the second chip island.

5. The semiconductor device of claim 1 wherein the ratio of thickness of the encapsulation material layer along the second face of the first chip island to the thickness of the encapsulation material layer at the second face of the second chip island of the leadframe is larger than 2.0.

6. The semiconductor device of claim 1 wherein the thickness of the encapsulation material layer along the second face of the first chip island is smaller than 1000 micrometer.

7. The semiconductor device of claim 1 wherein the thickness of the encapsulation material layer along the second face of the first chip island is smaller than 500 micrometer.

8. The semiconductor device of claim 1 wherein the thickness of the encapsulation material layer along the second face of the first chip island is larger than 1000 micrometer.

9. The semiconductor device of claim 1 wherein the first chip is a power transistor.

10. The semiconductor device of claim 1 wherein the second chip is a logic integrated circuit.

11. The semiconductor device of claim 1 wherein the first chip island of the leadframe and the second chip island of the leadframe are contiguous forming a combined chip island.

12. The semiconductor device of claim 11 wherein the combined chip island comprises a step between the first chip island and the second chip island of the leadframe.

13. The semiconductor device of claim 1 wherein the first chip island and the second chip island are arranged having a slit formed between the first chip island and the second chip island.

14. The semiconductor device of claim 1 further comprising a plurality of chip islands.

15. The semiconductor device of claim 1 further comprising a first wire bonded from the first chip to a leadframe output and a second wire bonded from the second chip to a leadframe output, the first wire shorter than the second wire to minimize wire sweep.

16. A method of encapsulating a semiconductor device comprising:
providing a leadframe having a first chip island and a second chip island, each chip island having a first face and a second face, the first chip island offset relative to the second chip island, the first chip island and the second chip island for receiving semiconductor chips;
fixing a first chip to the first surface of the leadframe at the first chip island;
fixing a second chip to the first surface of the leadframe at the second chip island:
wire bonding wires to the first and second chips;
arranging a mold frame with respect to the second surface of the leadframe to form a gap between the second surface of the first chip island and the second chip island and a surface of the mold frame; and
encapsulating with an encapsulation material flowing into the gap to form an encapsulation material layer covering the second face of first chip island and the second face of the second chip island, the thickness of the encapsulation material layer along the second face of the first chip island being different from the thickness of the encapsulation material layer along the second face of the second chip island.

17. The method of claim 16 wherein the thickness of the encapsulation material layer at the second face of the first chip island is larger than the thickness of the encapsulation material layer at the second face of the second chip island.

18. The method of claim 16 wherein the ratio of thickness of the encapsulation material layer along the second face of the first chip island to the thickness of the encapsulation material layer along the second face of the second chip island is larger than 2.0.

19. The method of claim 16 wherein the thickness of the encapsulation material layer along the second face of the first chip island is smaller than 1000 micrometer.

20. The method of claim 16 wherein the thickness of the encapsulation material layer at the second face of the first chip island is smaller than 500 micrometer.

21. The method of claim 16 wherein the thickness of the encapsulation material layer at the second face of the second chip island is larger than 1000 micrometer.

22. The method of claim 16 wherein the first chip island and the second chip island of the leadframe are contiguous forming a combined chip island.

23. The method of claim 22 wherein the combined chip island comprises a step between the first chip island of the leadframe and the second chip island of the leadframe.

24. The method of claim 16 wherein the first chip island and the second chip island are arranged having a slit formed between the first chip island and the second chip island.

25. The method of claim 16 wherein the leadframe further comprises a plurality of chip islands.

26. The method of claim 16 further comprising bonding a first wire from the first chip to a leadframe output and bonding a second wire from the second chip to a leadframe output, the first wire shorter than the second wire to minimize wire sweep.

27. A leadframe comprising a first chip island and a second chip island, each chip island having a first face and a second face; the first face of the first chip island for receiving a first chip, the first face of the second chip island for receiving a second chip, the first chip island offset relative from the second chip island.

28. The leadframe of claim 27 further comprising a plurality of chip islands.

29. The leadframe of claim 27 wherein the first chip island is a first downset and the second chip island is a second downset, the first downset offset relative to the second downset.

30. A method of making a multi-downset leadframe comprising providing a leadframe having a first surface and a second surface; stamping a first chip island for receiving a first semiconductor chip; and stamping a second chip island offset relative to the first chip island for receiving a second semiconductor chip.

31. The method of claim 30 comprising stamping a plurality of chip islands.
